(19) United States
(12) Patent Application Publication
(10) Pub. No.: US 2004/0179696 A1
(43) Pub. Date: Sep. 16, 2004

(54) Sound field control system and sound field controlling method, as well as sound field space characteristic decision system and sound field space characteristic deciding method

(75) Inventor: Yoshiki Ohta, Tsurugashima-shi (JP)

Correspondence Address: MORGAN LEWIS & BOCKIUS LLP, 1111 PENNSYLVANIA AVENUE NW, WASHINGTON, DC, 20004, US

(73) Assignee: PIONEER CORPORATION

(21) Appl. No.: 10/798,944

(22) Filed: Mar. 12, 2004

(30) Foreign Application Priority Data
Mar. 13, 2003 (JP) P2003-67814

(51) Int. Cl. H04R 29/00; H03G 3/00

(52) U.S. Cl. 381/56; 381/61

(57) ABSTRACT

A sound field characteristic decision system SI measures the impulse response of a sound field 10 to be reproduced, divides the measured impulse response into a plurality of blocks for frequency components and time components, and calculates a weighted linear sum based on a weight coefficient of each of the blocks, so that a sense of spaciousness in the sound field 10 is decided. A sound field control system SF calculates information to be added for each of the blocks according to a difference from a sense of spaciousness in a desired sound field, adds the calculated information to a sound source, and performs synthesis again.

### BACKGROUND OF THE INVENTION

1. Field of the Invention

The present invention relates to a technical field of a sound field control system and a sound field controlling method.

2. Related Art

Recently the arrival of new audio media has diversified audio reproduction environments. For this reason, systems for providing realistic sound in any audiovisual environment are demanded.

A number of so-called reverberating devices are proposed as systems for providing realistic sound.

In conventional reverberating devices, an initial reflected sound generating section of a finite length is provided in the previous stage of a system and an output signal is added to a reproduction sound source in a reverberation generating section of the subsequent stage. The reverberation generating section generally has IIR filters (Infinite Impulse Response) arranged in parallel. In addition, a proposal is made about convolution of an impulse response of an actual sound field with a reproduction sound source.

Similarly, a system such as a transaural reproduction system using an inverse filter is proposed as a system for providing realistic sound. The transaural reproduction system enables a listener in a reproduction sound field to listen to sound collected at the listening position of a desired sound space. Thus, this system achieves realism as if the listener were in the desired sound space to listen to the sound.

However, in the conventional reverberating devices, a reverberation characteristic and the like are determined and provided uniquely based on the intuition and experience of the designer without consideration of a characteristic such as the size of a space in a reproduction sound field. Thus, suitable sound reproduction is not performed for an acoustic characteristic of each reproduction sound field.

Further, in the conventional transaural reproduction systems, although realism of an original sound field is obtained at the most proper listening position, since a control area is small, realism becomes different from that of the original sound field at a position slightly away from the most proper position. Particularly in the case of reproduction in a small space, it is necessary to precisely localize the original sound field and control reverberation and the like, so that it is difficult to design intricate inverse filters.

### SUMMARY OF THE INVENTION

The present invention is devised in view of the above-described problems. An example of its object is to provide a sound field control system and a sound field controlling method whereby acoustic information is added according to an acoustic characteristic of each reproduction sound field to obtain reproduction sound as realistic as the original sound field.

The present invention will be described below. Although reference numerals in the accompanying drawings will be accessorily written as parenthetic numerals for descriptive convenience, the present invention is not limited to the illustrated features.

The above object of the present invention can be achieved by a sound field control system (SF) provided with: a characteristic measuring device (2) which measures an impulse response of a target sound field serving as a sound field to be reproduced; a characteristic dividing device (3) which divides the measured impulse response into two or more for predetermined frequency bands and into two or more for predetermined elapsed times, so that the impulse response is divided into a plurality of block data on a time axis and a frequency axis; a space characteristic deciding device (4) which decides, based on the divided block data, a target space characteristic serving as an acoustic characteristic of a space in the target sound field; a difference detecting device (5) which detects a difference between the decided target space characteristic and a predetermined desired space characteristic serving as an acoustic characteristic of a space in a desired sound field; a sound source dividing device (6) which divides a sound source component of a sound source for each of the predetermined frequency bands, the sound source being listened to in the target sound field; a correcting device (7) which corrects at least one sound source component for each of the sound source components based on the detected difference between the space characteristics; and a sound source synthesizing device (8) which synthesizes the sound source again based on the corrected sound source component.

The above object of the present invention can be achieved by a sound field control method provided with: a characteristic measuring process which measures an impulse response of a target sound field serving as a sound field to be reproduced; a characteristic dividing process which divides the measured impulse response into two or more for predetermined frequency bands and into two or more for predetermined elapsed times, so that the impulse response is divided into a plurality of block data on a time axis and a frequency axis; a space characteristic deciding process which decides, based on the divided block data, a target space characteristic serving as an acoustic characteristic of a space in the target sound field; a difference detecting process which detects a difference between the decided target space characteristic and a predetermined desired space characteristic serving as an acoustic characteristic of a space in a desired sound field; a sound source dividing process which divides a sound source component of a sound source for each of the predetermined frequency bands, the sound source being listened to in the target sound field; a correcting process which corrects at least one sound source component for each of the sound source components based on the detected difference between the space characteristics; and a sound source synthesizing process which synthesizes the sound source again based on the corrected sound source component.

The above object of the present invention can be achieved by a recording medium on which a sound field controlling program is recorded so as to be readable through a computer, wherein the sound field controlling program causes the computer to function as: a characteristic measuring device (2) which measures an impulse response of a target sound field serving as a sound field to be reproduced; a characteristic dividing device (3) which divides the measured impulse response into two or more for predetermined frequency bands and into two or more for predetermined elapsed times, so that the impulse response is divided into a plurality of block data on a time axis and a frequency axis; a space characteristic deciding device (4) which decides, based on the divided block data, a target space characteristic serving as an acoustic characteristic of a space in the target sound field; a difference detecting device (5) which detects a difference between the decided target space characteristic and a predetermined desired space characteristic serving as an acoustic characteristic of a space in a desired sound field; a sound source dividing device (6) which divides a sound source component of a sound source for each of the predetermined frequency bands, the sound source being listened to in the target sound field; a correcting device (7) which corrects at least one sound source component for each of the sound source components based on the detected difference between the space characteristics; and a sound source synthesizing device (8) which synthesizes the sound source again based on the corrected sound source component.

The above object of the present invention can be achieved by a sound field space characteristic decision system (SI) provided with: a characteristic measuring device (2) which measures an impulse response of a target sound field serving as a sound field to be reproduced; a characteristic dividing device (3) which divides the measured impulse response into two or more for predetermined frequency bands and into two or more for predetermined elapsed times, so that the impulse response is divided into a plurality of block data on a time axis and a frequency axis; and a space characteristic deciding device (4) which decides, based on the divided block data, a target space characteristic serving as an acoustic characteristic of a space in the target sound field.

The above object of the present invention can be achieved by a sound field space characteristic decision method provided with: a characteristic measuring process which measures an impulse response of a target sound field serving as a sound field to be reproduced; a characteristic dividing process which divides the measured impulse response into two or more for predetermined frequency bands and into two or more for predetermined elapsed times, so that the impulse response is divided into a plurality of block data on a time axis and a frequency axis; and a space characteristic deciding process which decides, based on the divided block data, a target space characteristic serving as an acoustic characteristic of a space in the target sound field.

The above object of the present invention can be achieved by a recording medium on which a sound field space characteristic deciding program is recorded so as to be readable through a computer, wherein the sound field space characteristic deciding program causes the computer to decide a characteristic of a sound field space, and to function as: a characteristic measuring device (2) which measures an impulse response of a target sound field serving as a sound field to be reproduced; a characteristic dividing device (3) which divides the measured impulse response into two or more for predetermined frequency bands and into two or more for predetermined elapsed times, so that the impulse response is divided into a plurality of block data on a time axis and a frequency axis; and a space characteristic deciding device (4) which decides, based on the divided block data, a target space characteristic serving as an acoustic characteristic of a space in the target sound field.

### BRIEF DESCRIPTION OF THE DRAWINGS

FIG. 1 is a functional block diagram showing an example of the schematic configuration of a sound field space characteristic decision system and a sound field control system according to the present invention;

FIG. 2 is a diagram showing an example of the detailed configuration of a sound field space characteristic decision system 2 according to the present invention;

FIG. 3 is a chart showing an example of evaluation values indicating a sense of spaciousness;

FIG. 4 is a diagram showing an example of the relationship between a reverberation characteristic calculated by an impulse response and a frequency band; FIG. 4A is a diagram showing an example of a reverberation characteristic in a low frequency band; FIG. 4B is a diagram showing an example of a reverberation characteristic in a high frequency band;

FIG. 5 is a diagram showing an example of a time/frequency division;

FIG. 6 is a graph showing an example of a weight coefficient of a source 1 based on experimental results;

FIG. 7 is a graph showing an example of a weight coefficient of a source 2 based on experimental results; and

FIG. 8 is a flowchart showing sound field controlling operations performed by a sound field control system SF according to an embodiment.

### DESCRIPTION OF THE PREFERRED EMBODIMENTS

The following will describe an embodiment of a sound field space characteristic decision system and a sound field control system, which use a method of deciding a sense of spaciousness felt by a person in a sound field.

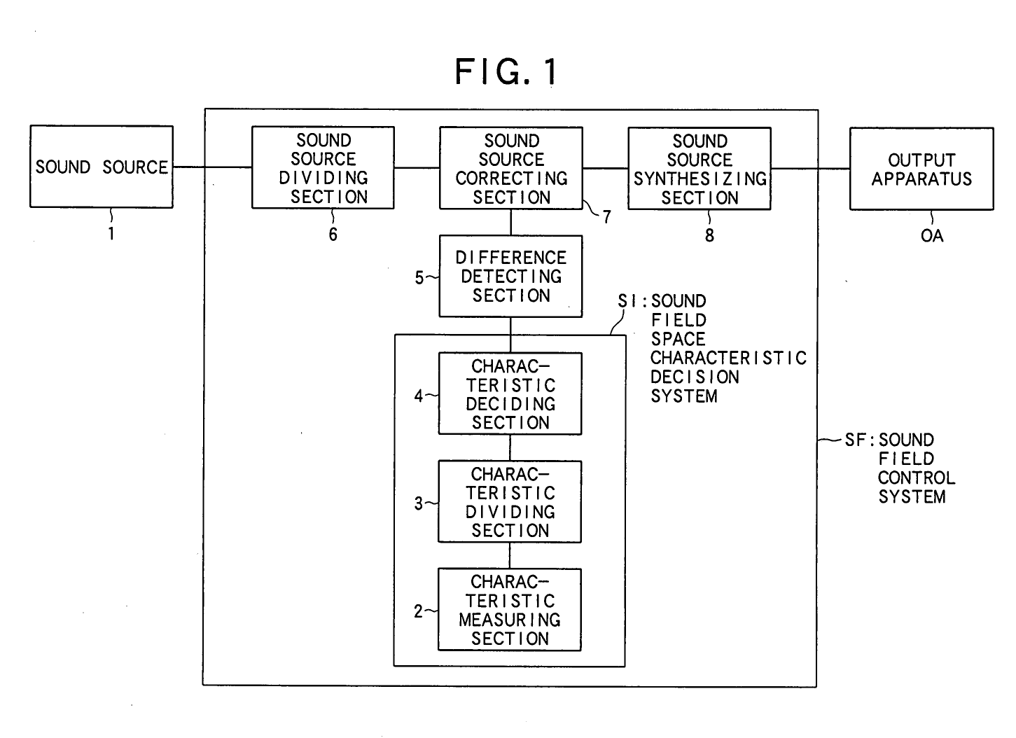

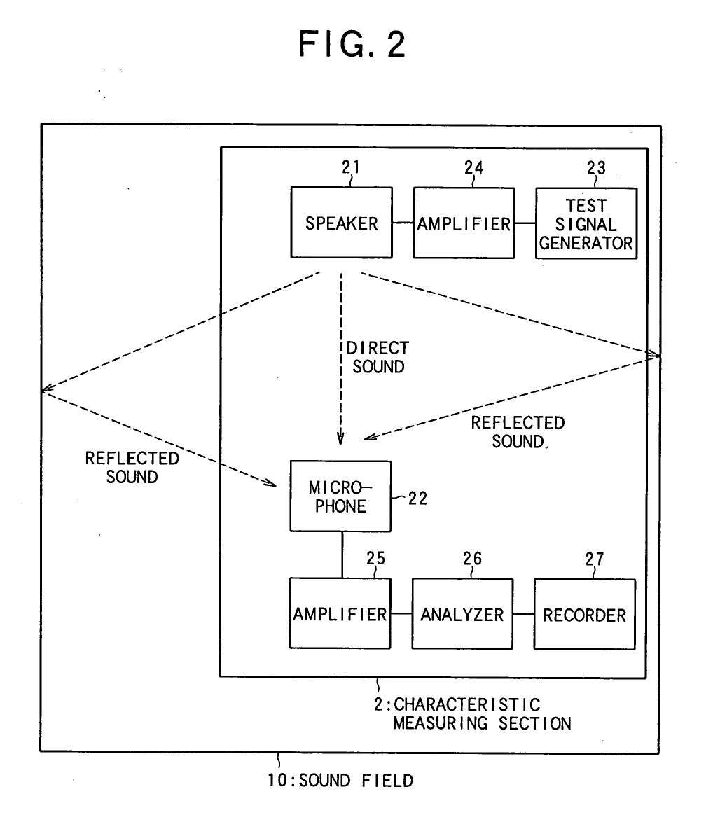

Referring to FIGS. 1 and 2, the schematic configuration of the sound field space characteristic decision system will be described below.

FIG. 1 is a functional block diagram showing an example of the schematic configuration of the sound field space characteristic decision system and the sound field control system according to the present invention. FIG. 2 is a diagram showing an example of the detailed configuration of a sound field space characteristic decision system 2 according to the present invention.

As shown in FIG. 1, a sound field control system SF of the present embodiment is constituted of a characteristic measuring section 2, a characteristic dividing section 3, a characteristic deciding section 4, a difference detecting section 5, a sound source dividing section 6, a sound source correcting section 7, and a sound source synthesizing section 8.

The characteristic measuring section 2, the characteristic dividing section 3, and the characteristic deciding section 4 constitute a sound field space characteristic decision system SI.

For example, the characteristic measuring section 2 works as a characteristic measuring device of the present invention, the characteristic dividing section 3 works as a characteristic dividing device of the present invention, and the characteristic deciding section 4 works as a space characteristic deciding device of the present invention. Further, the difference detecting section 5 works as a difference detecting device of the present invention, the sound source dividing section 6 works as a sound source dividing device of the present invention, and the sound source correcting section 7 works as a correcting device, an added information calculating device, and an information adding device of the present invention. Moreover, the sound source synthesizing section 8 works as a sound source synthesizing device of the present invention.

First, the characteristic measuring section 2 measures an impulse response of a target sound field serving as a sound field to be reproduced. The detailed configuration of the characteristic measuring section 2 will be described later.

The characteristic dividing section 3 divides a measured impulse response into two or more for predetermined frequency bands and divides the impulse response into two or more for predetermined elapsed times, so that the impulse response is divided into a plurality of block data in a matrix form on a time/frequency axis.

The division for predetermined frequency bands is not limited to a specific bandwidth but includes different bandwidths.

Similarly, the predetermined elapsed time is not limited to a specific time but includes different time widths. The elapsed time indicates an elapsed time having 0 msec as the arrival time of direct sound. Each of the dividing methods will be described later.

The characteristic deciding section 4 decides a sense of spaciousness as an acoustic characteristic of the target sound field space based on the divided block data, and converts the sense of spaciousness into a number as a specific evaluation value.

The target sound field indicates a reproduction sound field where the listener listens to sound. An example of the reproduction sound field includes a listener's room at home and a seat space in an automobile.

Further, a sense of spaciousness indicates one of acoustic characteristics about a space of a sound field. A sense of spaciousness is felt by a person as a sense of the size of the sound field. A numeric characteristic of a sense of spaciousness numerically represents, as an evaluation value, the degree of speciousness for a sound field, perceived by a person through listening to reverberation which is varied for the capacities of the sound field. A method of calculating an evaluation value indicating a sense of spaciousness will be described later.

The difference detecting section 5 compares an evaluation value which indicates the decided sense of spaciousness of the target sound field, with an evaluation value which indicates a sense of spaciousness of a desired sound field as a desired space characteristic predetermined as a space characteristic of a desired sound field, so as to detect a difference between the values.

The desired sound field indicates a sound field for which realism is demanded as if the listener listened to music and so on in a concert hall and a live house. In general a target sound field is smaller than a desired sound field.

The sound source dividing section 6 divides a sound source 1, which serves as a reproduction target, into a plurality of sound source components for predetermined frequency bands. The frequency band to be divided is the same as the sound field space characteristic decision system SI.

The sound source correcting section 7 comprises the same number of reflected sound adding filters as the number of the divided frequency components. The sound source correcting section 7 corrects sound source components so as to have equal evaluation values based on a difference between an evaluation value which indicates a sense of spaciousness in the target sound field and an evaluation value indicating a sense of spaciousness in the desired sound field. The difference is detected by the difference detecting section 5.

The sound source synthesizing section 8 synthesizes a signal again for each frequency band where a reflected sound pattern is added to sound source components, and outputs the synthesized signal to an output apparatus OA.

Referring to FIG. 2, the detailed configuration of the characteristic measuring section 2 will be described below.

As shown in FIG. 2, for example, the characteristic measuring section 2 is disposed in a sound field 10, which serving as a target sound field, to measure an impulse response of the target sound field.

As shown in FIG. 2, the characteristic measuring section 2 is constituted of a speaker 21 for amplifying signal sound for measurement, a microphone 22 disposed at a certain distance away from the speaker 21, a test signal generator 23 which generates a test signal for driving the speaker 21, an amplifier 24 which drives the speaker 21, an amplifier 25 which adjusts a level of sound received by the microphone 22, an analyzer 26 which calculates an impulse response from a test signal of the test signal generator 23 and a sound wave signal collected by the microphone 22, and a recorder 27 which records a calculated impulse response.

For example, the speaker 21 of the present embodiment constitutes an amplifying device of the present invention and the test signal generator 23 constitutes a signal generating device of the present invention. Moreover, the microphone 22 constitutes a collecting device of the present invention and the analyzer 26 constitutes a response calculating device of the present invention.

Subsequently, a method of measuring an impulse response in the characteristic measuring section 2 will be described below.

First, the test signal generator 23 generates a test signal such as an impulse signal, the test signal from the test signal generator 23 is amplified to a predetermined level by the amplifier 24, and the output of the amplifier 24 is inputted to the speaker 21 to generate sound in the sound field 10.

The microphone 22 collects the sound generated in the sound field 10. The microphone 22 is disposed at a predetermined position away from the speaker 21.

As shown in FIG. 2, sound from the speaker 21 includes direct sound which directly reaches the microphone 22 and reflected sound (indirect sound) which reaches the microphone 22 after being reflected on the wall, the ceiling, the floor, and the like of the sound field 10. These sounds represent the characteristics of the impulse response.

The amplifier 25 amplifies a signal of sound, which is collected by the microphone 22, to a predetermined level. The analyzer 26 calculates an impulse response from the amplified signal and records the response in the recorder 27.

Although the analyzer 26 and the recorder 27 are used in the present embodiment, a personal computer and the like having a measurement program may be used instead of the analyzer 26 and the recorder 27.

Moreover, although the impulse signal is used as a test signal in the present embodiment, the inputted signal is not limited to an impulse signal. For example, M-sequence noise, a time stretched pulse and the like may be used.

In this way, the impulse response of the sound field is measured and the measured impulse response is used to calculate an evaluation value serving as a numerical characteristic, which indicates a sense of spaciousness of the sound field.

The following will describe a principle of calculating an evaluation value in the sound field space characteristic decision system SI. The evaluation value serves as a numerical characteristic indicating a sense of spaciousness of a sound field.

First, such an evaluation value is calculated by a subjective evaluation experiment using, for example, impulse responses of various rooms.

To be specific, in a plurality of rooms having different capacities and so on, impulse responses measured by the characteristic measuring section 2 are convoluted with sound sources by using the configuration of FIG. 2, so that a plurality of stimulus sounds are generated. Further, in order to minimize a change in the timbre of the stimulus sounds during reproduction, all the impulse responses are corrected so that frequency characteristics become almost flat in an audible frequency band.

In this subjective evaluation experiment, for example, two of the plurality of stimulus sounds are paired and are reproduced at random through headphones, so that it is possible to obtain audible images of two or more test subjects regarding the width of sound.

To consider a different result for each sound source, for example, two sound sources of a sound (hereinafter, referred to as “source 1”) and a drum (hereinafter, referred to as “source 2”) are used which have completely different qualities. For the experimental results, evaluation values are calculated using Thurstone's law of comparative judgment (Case V).

Thurstone's law of comparative judgment (Case V) is a principle of calculating an evaluation value by using an interval scale. The interval scale is a value indicating a psychologically equal distance by a numerically equal distance. Therefore, the interval scale has no origin point and has significance on each difference between the values.

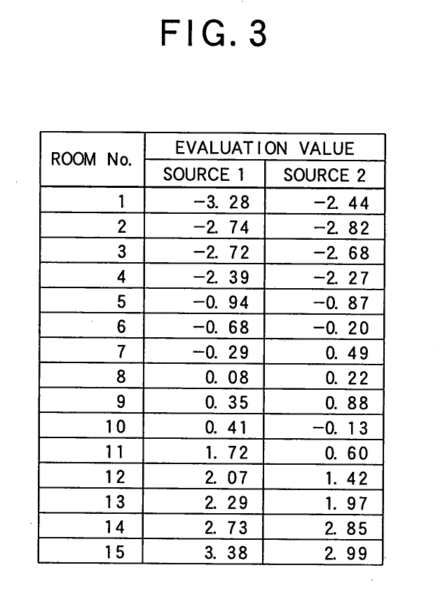

FIG. 3 shows an example of the calculated evaluation values.

FIG. 3 shows a chart indicating an example of evaluation values calculated in the above experiment.

As shown in FIG. 3, the source 1 and the source 2 demonstrate close tendencies of evaluation values in each room.

The following will describe a method of calculating an evaluation value indicating a sense of spaciousness of a target sound field, based on evaluation value data obtained thus.

First, the characteristic dividing section 3 divides the impulse response, which is measured by the characteristic measuring section 2 for the sound field, into a plurality of block data in a matrix form for given frequency bands and elapsed times on a time/frequency axis.

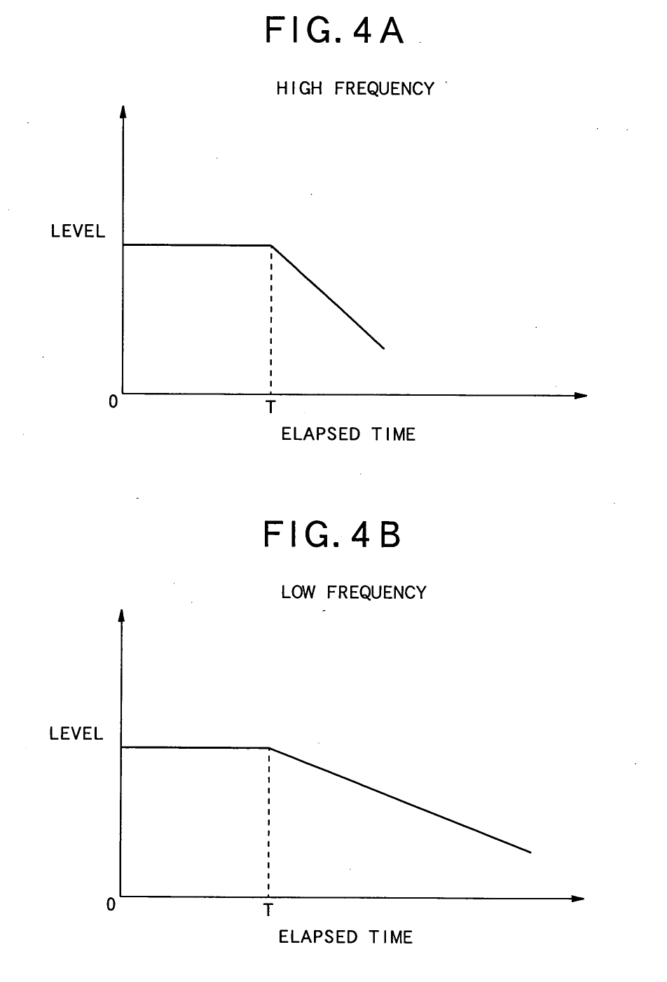

Referring to FIG. 4, the following will discuss the reason why an impulse response is divided on the time/frequency axis.

FIG. 4 is a diagram showing an example of the relationship between a frequency band and a reverberation characteristic calculated by an impulse response. FIG. 4A is a diagram showing an example of a reverberation characteristic in a low frequency band, and FIG. 4B is a diagram showing an example of a reverberation characteristic in a high frequency band.

As described above, sound includes direct sound and reflected sound. The reverberation characteristic calculated by an impulse response relates to the attenuation of reflected sound.

As shown in FIGS. 4A and 4B, after a specific time T, attenuation proceeds with the passage of time in this reverberation characteristic.

Further, the high frequency band of FIG. 4A has a reverberation characteristic of faster attenuation as compared with the low frequency band of FIG. 4B.

In this way, a reverberation characteristic calculated by an impulse response is varied for each elapsed time and frequency band. For this reason, the characteristic dividing section 3 of the present embodiment divides an impulse response into a plurality of block data on the time/frequency axis.

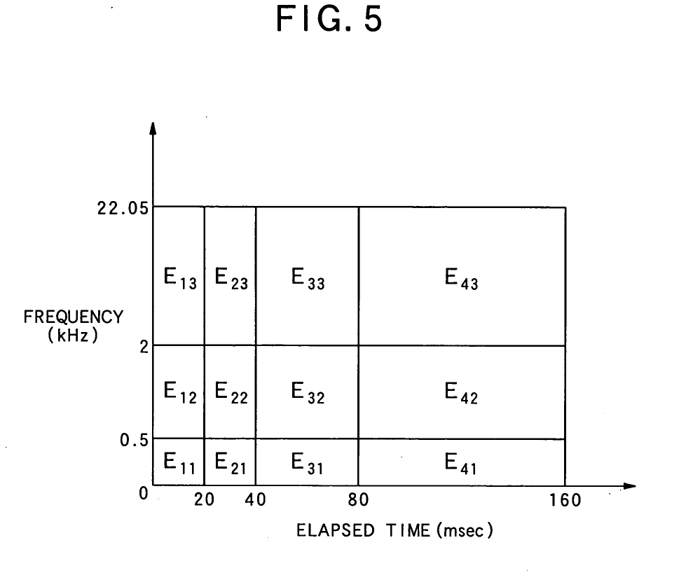

Referring to FIG. 5, the following will describe time/frequency division performed in the characteristic dividing section 3.

FIG. 5 is a diagram showing an example of time/frequency division.

As shown in FIG. 5, the characteristic dividing section 3 makes a division into 12 blocks in total in a matrix form having four blocks along a time axis and three blocks along a frequency axis.

First along the frequency axis, the characteristic dividing section 3 makes a division into three relative to a human voice band (500 Hz to 2 kHz).

Further, along the time axis, the characteristic dividing section 3 makes a division into four relative to 80 msec, which is generally known as an elapsed time deciding whether or not sound is dividedly heard by a person.

In FIG. 5, 0 msec on the time axis indicates a time when direct sound arrives.

Then, the characteristic deciding section 4 calculates energy of each block data divided by the characteristic dividing section 3. The following will discuss the calculating steps of E₂₂ as an example of a calculating method of Eᵢⱼ that is performed in the characteristic deciding section 4, where Eᵢⱼ represents an energy of an impulse response included in each block data.

Regarding an impulse response p(t) to be analyzed, the characteristic deciding section 4 first filters E₂₂ with a band-pass filter h₂ (t) corresponding to components of 500 Hz to 2 kHz. Normalization is performed by a bandwidth to calculate an energy series e(t).

For example, a linear phase FIR (Finite Impulse Response) is set as the band-pass filter h₂(t)

$$e ( t ) = \frac{1}{2000 - 500} \cdot {( {\int }_{- ∞}^{∞} h ( τ ) \cdot p ( t - τ ) ⅆ τ )}^{2} \qquad ( Formula 1 )$$

The characteristic deciding section 4 integrates e(t) on the time axis and normalizes e(t) by a time width to calculate E₂₂, where tₒ represents a time when sound directly arrives.

$${E}_{22} = \frac{1}{0.04 - 0.02} {\int }_{{t}_{0} + 20 ms}^{{t}_{0} + 40 ms} e ( t ) ⅆ t \qquad ( Formula 2 )$$

The characteristic deciding section 4 similarly calculates energy of a block data other than E₂₂ and normalizes Eᵢⱼ after calculation.

$${\sum }_{i = 1}^{4} {\sum }_{j = 1}^{3} {E}_{i j} = 1 \qquad ( Formula 3 )$$

In this way, when an impulse response p(t) of a room is obtained, energy Eᵢⱼ is calculated. An evaluation value R indicating a sense of spaciousness is represented by a weighted linear sum of Eᵢⱼ using a weight coefficient (regression coefficient) Wᵢⱼ, as in the formula below.

$$R = {\sum }_{i = 1}^{4} {\sum }_{j = 1}^{3} {W}_{i j} \cdot {E}_{i j} \qquad ( Formula 4 )$$

Multiple regression analysis is performed while the evaluation value R obtained in the above experiment and so on is used as a subject variable and the energy Eᵢⱼ of a corresponding impulse response is used as an explanatory variable, so that a weight coefficient Wᵢⱼ is calculated.

In this way, the weight coefficient Wᵢⱼ is determined beforehand, for each block data, as a coefficient indicating a contributing degree in the calculation of the evaluation value R. When the weight coefficient Wᵢⱼ is positive, the larger the energy value of the block data is, the larger the evaluation value R is. Conversely, when the weight coefficient Wᵢⱼ is negative, the larger the energy value of the block data is, the smaller the evaluation value R is.

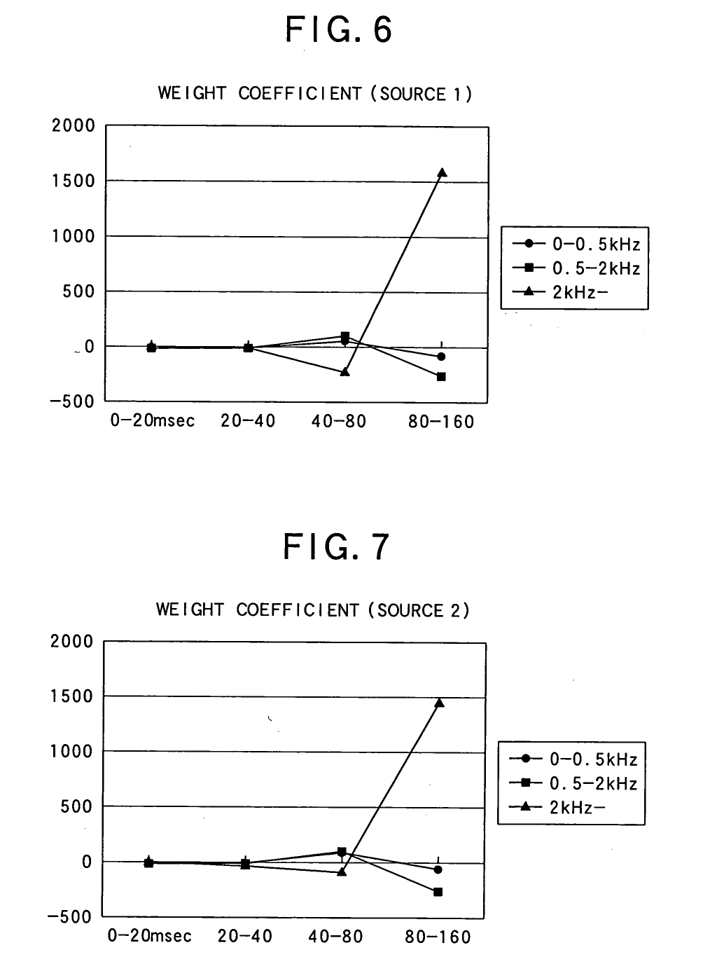

Referring to FIGS. 6 and 7, an example of the weight coefficient Wᵢⱼ will be described below.

FIG. 6 is a graph showing an example of a weight coefficient of the source 1 based on experimental results. FIG. 7 is a graph showing an example of a weight coefficient of the source 2 based on experimental results.

As shown in FIGS. 6 and 7, the sources have similar shapes of coefficients in the graphs. An overall changing degree of the sense of spaciousness R is varied for each block data. The change is caused by an increase or decrease in the energy value of each block data. Particularly E₄₃ has a large weight coefficient in a block having a band exceeding a frequency of 2 kHz and an elapsed time of 80 to 160 msec.

This means that the evaluation value R indicating an overall sense of spaciousness is greatly affected by an increase or decrease in the component value of E₄₃ having a high weight coefficient.

As described above, the evaluation value indicating a sense of spaciousness is calculated by (Formula 4) using a weighted linear sum of a discrete energy distribution on a time/frequency plane. Moreover, the time/frequency structure of reflected sound is arbitrarily changed to control the evaluation value, so that a sense of spaciousness felt by a person can be changed.

On the basis of this principle, the following will describe a specific method of correcting a sound source component. The method is performed by the sound source correcting section 7 according to the present embodiment.

As described above, when the weight coefficient Wᵢⱼ is positive, the larger the energy value of the block data is, the larger the evaluation value R is. Conversely, when the weight coefficient Wᵢⱼ is negative, the larger the energy value of the block data is, the smaller the evaluation value R is.

Therefore, when an evaluation value Rₛₘₐₗₗ indicating a sense of spaciousness of the sound field 10 is increased, that is, when a change is made to a reverberation characteristic of a wider sound field, the sound source correcting section 7 calculates added information so as to increase the energy value in the block having a positive weight coefficient Wᵢⱼ. Then, the sound source correcting section 7 corrects a reflected sound adding filter of the corresponding band and corrects a sound source component.

On the other hand, for example, when the evaluation value Rₛₘₐₗₗ indicating a sense of spaciousness of the sound field 10 is increased too much due to the correction and is changed to a reverberation characteristic of a smaller sound field, the sound source correcting section 7 calculates added information so as to increase the energy value in the block having a negative weight coefficient Wᵢⱼ. Then, the sound source correcting section 7 corrects a reflected sound adding filter of the corresponding band and corrects a sound source component.

Further, as a method of determining specific added information, the sound source correcting section 7 compares, for example, the energy distribution of a desired sound field and the energy distribution of a target sound field in each block, and determines added information so as to earlier correct a block having a larger difference.

Besides, the sound source correcting section 7 calculates added information and corrects a filter so as to make corrected sound more natural.

To be specific, natural sound has the property of attenuating energy with the passage of time and empirical facts dictate that exponential attenuation generates natural sound for human ears. Further, the higher the frequency is, the sharper the decay curve is. Thus, the sound source correcting section 7 corrects a sound source component in compliance with these patterns.

The following is also applicable: when the sound source correcting section 7 calculates added information and corrects a filter, all the blocks are not used as targets, E₄₃ having a large weight coefficient and greatly affecting a sense of spaciousness among the blocks is used as a target, and a sound source component is corrected so as to increase an energy value of E₄₃.

For the same reason, for example, the sound source correcting section 7 can also correct a sound source component so as to increase energy values of E₄₃ and E₄₂ that belong to an elapsed time exceeding a predetermined time, which is 80 msec in the present embodiment.

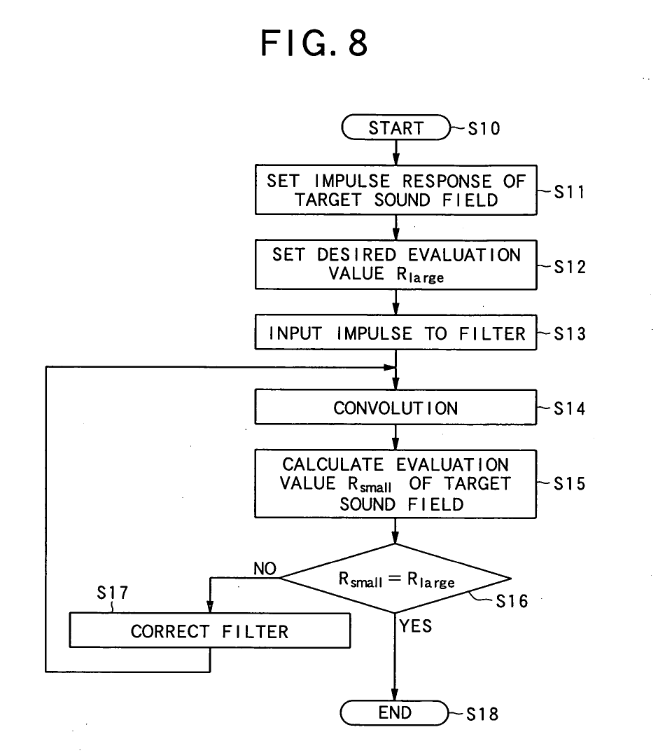

Referring to FIG. 8, the following will describe the decision of a sense of spaciousness in the sound field space characteristic decision system and sound field control using the method of correcting a sound source component.

FIG. 8 is a flowchart showing sound field control performed by the sound field control system SF of the present embodiment.

First when an instruction to control a sound field is received from a control section (not shown), the sound source correcting section 7 sets an impulse response hₛₘₐₗₗ of the sound field 10 to be reproduced (step S11).

Then, the difference detecting section 5 sets an evaluation value R_{large} indicating a sense of spaciousness of a desired sound field such as a concert hall (step S12).

Subsequently, the sound source correcting section 7 sets reflected sound added filters for divided frequency bands (step S13). In this case, divided bands are three.

Then, the characteristic deciding section 4 performs convolution on the impulse response hₛₘₐₗₗ of the sound field 10 to be reproduced and the combined filters, and calculates a value H (step S14).

$$H = ( {\sum }_{i} BPF\_i ⊗ FILT\_i ) ⊗ {h}_{small} \qquad ( Formula 5 )$$

Subsequently, the characteristic deciding section 4 calculates an evaluation value Rₛₘₐₗₗ, which indicates a sense of spaciousness of the sound field 10, after convolution by using Formula 4 provided for an evaluation value indicating a sense of spaciousness, and outputs the calculating result to the difference detecting section 5 (step S15).

Then, the difference detecting section 5 detects a difference between the evaluation value Rₛₘₐₗₗ, which is calculated by the characteristic deciding section 4 and indicates a sense of spaciousness of the sound field 10, and the evaluation value R_{large}, which indicates a desired sense of spaciousness, and judges whether or not the values are equal to each other (step S16).

When the difference detecting section 5 judges that the evaluation value Rₛₘₐₗₗ indicating a sense of spaciousness of the sound field 10 and the evaluation value R_{large} indicating a desired sense of spaciousness are not equal to each other (step S16, No), the sound source correcting section 7 calculates information to be added to a sound source component based on the difference detected by the difference detecting section 5 in order to make fine corrections on one of the reflected sound added filters, and corrects the reflected sound added filter of the sound source correcting section 7 (step S17). The method of calculating added information and the method of correcting the reflected sound added filter in the sound source correcting section 7 were described above.

After the filter is corrected, a return is made to step S14 and the difference detecting section 5 detects a difference between R_{large} and corrected Rₛₘₐₗₗ.

On the other hand, in the judgment of step S16, when the difference detecting section 5 judges that the evaluation value Rₛₘₐₗₗ indicating a sense of spaciousness of the sound field 10 is equal to the evaluation value R_{large} indicating a desired sense of spaciousness (step S16, Yes), a series of operations is completed (step S18).

Hence, after a series of sound field controlling operations is completed, for example, the reproduction of music is started by using the corrected reflected sound added filter, so that the listener can feel a desired sense of spaciousness.

Besides, the data of the impulse response hₛₘₐₗₗ is measured beforehand in a target sound field such as a seat space in an automobile by using, for example, the above measuring method, and data recorded in the recorder 27 can be used. Also, the data of the evaluation value R_{large} indicating a desired sense of spaciousness in the sound field is similarly recorded beforehand in the recorder 27 and can be used.

As described above, the present embodiment comprises the characteristic measuring section 2 which measures an impulse response of the sound field 10 to be reproduced, the characteristic dividing section 3 which divides a measured impulse response into two or more for predetermined frequency bands and divides the impulse response into two or more for predetermined elapsed times, so that the impulse response is divided into a plurality of block data on the time axis and the frequency axis, the characteristic deciding section 4 which decides a target space characteristic serving as an acoustic characteristic of a space in the sound field 10 based on the divided block data, the difference detecting section 5 which detects a difference between the decided target space characteristic and a desired space characteristic predetermined as an acoustic characteristic of a space in a desired sound field, the sound source dividing section 6 which divides, in the sound source 1 to be listened to in the sound field 10, a sound source component for each of the predetermined frequency bands, the sound source correcting section 7 which corrects at least one sound source component for each sound source component based on a detected difference between the space characteristics, and the sound source synthesizing section 8 which synthesizes the sound source again based on the corrected sound source component.

Therefore, an impulse response of a target sound field is measured, the space characteristic of the target sound field is decided by dividing the impulse response into a plurality of blocks for predetermined frequencies and elapsed times, a difference from a desired space characteristic is detected, and the sound source of at least one of the blocks is corrected, according to the detection result, regarding sound to be listened to in the target sound field.

In this way, a reflected sound pattern varied for each frequency and elapsed time is divided into a plurality of blocks, so that the space characteristic of a target sound field, for example, a sense of spaciousness of the sound field felt by a person can be decided. Thus, it is possible to provide the sound field space characteristic decision system used for controlling a sound field and designing an acoustic hall.

Further, according to a difference in space characteristic from a desired sound field, information to be added to the sound source is calculated and the sound source to be reproduced is corrected for each predetermined block, so that it is possible to provide the sound field control system which can readily obtain realism, even in a small listening space, as if the listener were in a desired sound field such as a large concert hall.

According to the present embodiment, when the acoustic characteristic of a space is a numerical characteristic indicating a sense of spaciousness, which is a sense of the size of a sound field felt by a person, the characteristic deciding section 4 decides a space characteristic R based on a weighted linear sum of an energy value Eᵢⱼ of each block data and a weight coefficient Wᵢⱼ determined for each block data.

Therefore, the influence on a sense of spaciousness varied for each frequency and elapsed time in each block is calculated and decided by assigning a weight. Hence, it is possible to provide the sound field space characteristic decision system by which a sense of spaciousness felt by a person in a sound field can be represented by an objective evaluation value.

Further, a sound field is controlled for each block based on a difference between evaluation values. Thus, it is not necessary to perform precise filter control which is required in the conventional art, a filter can be designed in a short time, the number of divided frequency bands is reduced, and real-time processing is considerably reduced.

Moreover, since a sound field is controlled based on a difference between evaluation values, it is possible to provide the sound field control system enabling objective sound field control without depending upon the intuition and experience of the designer.

Moreover, according to the present embodiment, the characteristic measuring section 2 includes the speaker 21 for amplifying sound based on a test signal, the test signal generator 23 for generating the test signal, the microphone 22 for collecting sound generated from the speaker 21, and the analyzer 26 for calculating an impulse response between the speaker 21 and the microphone 22 based on the test signal and the collected sound.

An impulse response is calculated in the sound field space characteristic decision system SI, so that it is possible to provide the sound field space characteristic decision system, which can readily measure the space characteristic of a target sound field, and the sound field control system using the decision system.

Further, according to the present embodiment, when a predetermined frequency band includes at least a band including predetermined low and medium frequencies and a band exceeding the low and medium frequencies, the sound source correcting section 7 corrects a sound source component included in the band exceeding the low and medium frequencies.

Therefore, a correction is made on reflected sound components in the low and medium frequencies which are important elements for a sense of spaciousness of a sound field, in view of the human auditory mechanism. Thus, it is possible to provide the sound field control system which can obtain a desired sense of spaciousness more effectively.

Furthermore, according to the present embodiment, the low and medium frequencies, which serve as predetermined frequencies for a division on the frequency axis, have values of 500 Hz to 2 kHz.

Therefore, a reflected sound component is corrected in a frequency band exceeding 2 kHz, which is generally recognized as the upper limit of the low and medium frequencies. Thus, it is possible to provide the sound field control system which can obtain a desired sense of spaciousness more effectively.

Moreover, according to the present embodiment, the sound source correcting section 7 corrects, relative to the time when direct sound arrives, a reflected sound component included in an elapsed time after a predetermined time from the arrival time.

Therefore, reflected sound is added to the sound source in an elapsed time exceeding a predetermined time (e.g., 80 msec), which is an important element for a sense of spaciousness in a sound field in view of the human auditory mechanism. Thus, it is possible to provide the sound field control system which can effectively obtain a desired sense of spaciousness.

The predetermined time can be arbitrarily changed for each genre of reproduced music such as classical music and rock. Thus, it is possible to control a sound field more effectively for each genre and so forth.

Moreover, according to the present embodiment, the sound source correcting section 7 calculates added information to be added to at least any one of sound source components based on a detected difference between space characteristics, and adds the calculated information to the sound source component, so that a correction is made.

Therefore, in the correcting method, it is only necessary to calculate added information and add the information to a sound source component. Hence, it is possible to provide the sound field control system which eliminates the necessity for precise filter control, which is required in the conventional art, permit a filter to be designed in a short time, and considerably reduce real-time processing.

In the present embodiment, the sound field space characteristic decision system SI is applied to the sound field control system SF, which adds information to a sound source and makes an adjustment so that a desired sense of spaciousness can be obtained in a target sound field. The application of the decision system is not limited to the above. For example, the sound field space characteristic decision system is also applicable to the design of a reproduction space such as an acoustic hall and a listening room. Further, the decision system is applicable to every field where a design is made and control is performed by using the decision of a sense of spaciousness as a yardstick to measure a space impression.

In the present embodiment, a sound field space characteristic is decided and a sound field is controlled by the above-described system configuration. The following configuration is also applicable: a system comprises a computer and a recording medium, the recording medium stores programs for deciding a sense of spaciousness and controlling a sound field, and the program for deciding the sense of spaciousness and the program for controlling a sound field are read by the computer, so that the same operations are performed as the above-described system configuration.

In the system for executing the program to decide the sound field space characteristic and the program to control a sound field, the recording medium may be constituted of a recording medium such as a DVD and a CD.

In this case, the system comprises a reader for reading the programs from the recording medium.

In the present embodiment, it is assumed that a single speaker has a single sound receiving point. The configuration is not limited. The present embodiment is also applicable to a stereo system and a multichannel system that comprise two speakers. For example, when a plurality of speakers are disposed at predetermined positions to perform reproduction, an impulse response is measured for each of the speakers and the operations described in steps S13 to S17 of FIG. 8 are repeated for the number of sound sources.

In the present embodiment, a division is made into 12 in total, which has four divisions in the time axis direction and three divisions in the frequency axis direction. The division is not particularly limited. A dividing method and the number of divisions may be arbitrarily decided on the time/frequency axis. Therefore, in consideration of various conditions including the genre of reproduced music and a used filter, it is possible to properly decide the number of divisions in the time axis direction, the number of divisions in the frequency axis direction, and a time and frequency serving as the reference for division.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

The entire disclosure of Japanese Patent Application No. 2003-067814 filed on Mar. 13, 2003 including the specification, claims, drawings and summary is incorporated herein by reference in its entirety.

What is claimed is:

1. A sound field control system, comprising:
a characteristic measuring device which measures an impulse response of a target sound field serving as a sound field to be reproduced;
a characteristic dividing device which divides the measured impulse response into two or more for predetermined frequency bands and into two or more for predetermined elapsed times, so that the impulse response is divided into a plurality of block data on a time axis and a frequency axis;
a space characteristic deciding device which decides, based on the divided block data, a target space characteristic serving as an acoustic characteristic of a space in the target sound field;
a difference detecting device which detects a difference between the decided target space characteristic and a predetermined desired space characteristic serving as an acoustic characteristic of a space in a desired sound field;
a sound source dividing device which divides a sound source component of a sound source for each of the predetermined frequency bands, the sound source being listened to in the target sound field;
a correcting device which corrects at least one sound source component for each of the sound source components based on the detected difference between the space characteristics; and
a sound source synthesizing device which synthesizes the sound source again based on the corrected sound source component.

2. The sound field control system according to claim 1, wherein
when the acoustic characteristic of the space is a numerical characteristic indicating a sense of spaciousness which is a sense of a size of a sound field felt by a person, the space characteristic deciding device decides the space characteristic based on a weighted linear sum of an energy value of each of the block data and a weight coefficient determined for each of the block data.

3. The sound field control system according to claim 1 or 2, wherein the characteristic measuring device comprises:
an amplifying device which amplifies sound based on a test signal;
a signal generating device which generates the test signal;
a collecting device which collects the sound generated from the amplifying device; and
a response calculating device which calculates an impulse response between the amplifying device and the collecting device based on the test signal and the collected sound.

4. The sound field control system according to any one of claims 1 to 3, wherein the correcting device corrects the sound source component included in a frequency band exceeding a predetermined frequency among the predetermined frequency bands.

5. The sound field control system according to any one of claims 1 to 4, wherein the correcting device corrects the sound source component included in an elapsed time exceeding a predetermined elapsed time among the predetermined elapsed times.

6. The sound field control system according to any one of claims 1 to 5, wherein the correcting device comprises:
an added information calculating device which calculates, based on the detected difference between the space characteristics, added information to be added to at least one of the sound source components; and
an information adding device which makes a correction by adding the calculated added information to the sound source component.

7. A sound field controlling method, comprising:
a characteristic measuring process which measures an impulse response of a target sound field serving as a sound field to be reproduced;
a characteristic dividing process which divides the measured impulse response into two or more for predetermined frequency bands and into two or more for predetermined elapsed times, so that the impulse response is divided into a plurality of block data on a time axis and a frequency axis;
a space characteristic deciding process which decides, based on the divided block data, a target space characteristic serving as an acoustic characteristic of a space in the target sound field;
a difference detecting process which detects a difference between the decided target space characteristic and a predetermined desired space characteristic serving as an acoustic characteristic of a space in a desired sound field;
a sound source dividing process which divides a sound source component of a sound source for each of the predetermined frequency bands, the sound source being listened to in the target sound field;
a correcting process which corrects at least one sound source component for each of the sound source components based on the detected difference between the space characteristics; and
a sound source synthesizing process which synthesizes the sound source again based on the corrected sound source component.

8. A recording medium on which a sound field controlling program is recorded so as to be readable through a computer, wherein the sound field controlling program causes the computer to function as:
a characteristic measuring device which measures an impulse response of a target sound field serving as a sound field to be reproduced;
a characteristic dividing device which divides the measured impulse response into two or more for predetermined frequency bands and into two or more for predetermined elapsed times, so that the impulse response is divided into a plurality of block data on a time axis and a frequency axis;
a space characteristic deciding device which decides, based on the divided block data, a target space characteristic serving as an acoustic characteristic of a space in the target sound field;
a difference detecting device which detects a difference between the decided target space characteristic and a predetermined desired space characteristic serving as an acoustic characteristic of a space in a desired sound field;
a sound source dividing device which divides a sound source component of a sound source for each of the predetermined frequency bands, the sound source being listened to in the target sound field;
a correcting device which corrects at least one sound source component for each of the sound source components based on the detected difference between the space characteristics; and
a sound source synthesizing device which synthesizes the sound source again based on the corrected sound source component.

9. A sound field space characteristic decision system, comprising:
a characteristic measuring device which measures an impulse response of a target sound field serving as a sound field to be reproduced;
a characteristic dividing device which divides the measured impulse response into two or more for predetermined frequency bands and into two or more for predetermined elapsed times, so that the impulse response is divided into a plurality of block data on a time axis and a frequency axis; and
a space characteristic deciding device which decides, based on the divided block data, a target space characteristic serving as an acoustic characteristic of a space in the target sound field.

10. The sound field space characteristic decision system according to claim 10, wherein
when the acoustic characteristic of the space is a numerical characteristic indicating a sense of spaciousness which is a sense of a size of a sound field felt by a person, the space characteristic deciding device decides the space characteristic based on a weighted linear sum of an energy value of each of the block data and a weight coefficient determined for each of the block data.

11. The sound field space characteristic decision system according to claim 10 or 11, wherein the characteristic measuring device comprises:
an amplifying device which amplifies sound based on a test signal;
a signal generating device which generates the test signal;
a collecting device which collects the sound generated from the amplifying device; and
a response calculating device which calculates an impulse response between the amplifying device and the collecting device based on the test signal and the collected sound.

12. A sound field space characteristic deciding method, comprising:
a characteristic measuring process which measures an impulse response of a target sound field serving as a sound field to be reproduced;
a characteristic dividing process which divides the measured impulse response into two or more for predetermined frequency bands and into two or more for predetermined elapsed times, so that the impulse response is divided into a plurality of block data on a time axis and a frequency axis; and
a space characteristic deciding process which decides, based on the divided block data, a target space characteristic serving as an acoustic characteristic of a space in the target sound field.

13. A recording medium on which a sound field space characteristic deciding program is recorded so as to be readable through a computer, wherein the sound field space characteristic deciding program causes the computer to decide a characteristic of a sound field space, and to function as:
a characteristic measuring device which measures an impulse response of a target sound field serving as a sound field to be reproduced;
a characteristic dividing device which divides the measured impulse response into two or more for predetermined frequency bands and into two or more for predetermined elapsed times, so that the impulse response is divided into a plurality of block data on a time axis and a frequency axis; and
a space characteristic deciding device which decides, based on the divided block data, a target space characteristic serving as an acoustic characteristic of a space in the target sound field.
